(19) United States
(12) Patent Application Publication
(10) Pub. No.: US 2026/0291229 A1
(43) Pub. Date: Sep. 24, 2026

(54) SYSTEM COMPRISING A POWER SUPPLYING AND/OR ABSORBING DEVICE CONNECTED TO A POWER SYSTEM AND A RELATED METHOD

(71) Applicant: Hitachi Energy Ltd, Zürich (CH)

(72) Inventor: Jon RASMUSSEN, Västra Frölunda (SE)

(21) Appl. No.: 19/490,120

(22) PCT Filed: Jun. 21, 2023
(86) PCT No.: PCT/EP2023/066857

§ 371 Date: Dec. 4, 2025

(51) Int. Cl. H02J 3/001; G01R 19/00; G01R 19/165; H02J 3/0012; H02J 103/30

(52) U.S. Cl. CPC H02J 3/00125; G01R 19/0053; G01R 19/16576; H02J 3/0012; H02J 2103/30

(57) ABSTRACT

A system comprises a power supplying and/or absorbing device, connected to a power system and configured for selectively supplying power to or absorbing power from the power system. A voltage sensing unit is configured to sense voltage(s) of the device at successive time instants. If the sensed voltage(s) of the device at a time instant exceed a threshold voltage value, values indicative of at least one voltage of the device at successive time instants are stored until the sensed voltage(s) of the power supplying and/or absorbing device does not exceed the threshold voltage value, thereby producing one or more pluralities of stored values, which each represents a transient overvoltage event. A controller is configured to, for each transient overvoltage event, obtain the stored values corresponding to the transient overvoltage event and determine parameters derived from the stored values, thereby producing parameter(s) which each characterizes the corresponding transient overvoltage event.

### TECHNICAL FIELD

The present invention generally relates to the field of power systems. More specifically, the present invention relates to a method in a system comprising a power supplying and/or absorbing device connected to a power system, and a system comprising a power supplying and/or absorbing device connected to a power system.

### BACKGROUND

A power system, such as a power transmission and/or distribution system and/or a power grid, may be used to, e.g., provide power to equipment in many industries. A device such as a Static Synchronous Compensator (STATCOM) can be used to provide or absorb reactive power and thereby regulate the voltage at the point of connection to the power system. STATCOMs and similar devices are subject to transient overvoltages coming from the power system. Such transient overvoltages may arise from lightning strikes, switching overvoltages, faults, or other contingencies in the power system. The transient overvoltages will be transferred through any transformers of the STATCOM (or a similar device), which may cause damage to other components of the STATCOM. STATCOMs and similar devices are generally provided with surge arresters for protection against surges, but the protection may not be effective against every possible transient condition. Transient overvoltages can cause temporary flashovers and stress on components of STATCOMs and similar devices.

The components may however not fail immediately following a transient overvoltage event, which may make it difficult to find the root cause of a tripping of a STATCOM or a similar device (e.g., a sudden disconnection from the power system) or a failure of one or more components of the STATCOM or some similar device.

### SUMMARY

In view of the foregoing, a concern of the present invention is to provide means for facilitating finding the root cause of any tripping of a Static Synchronous Compensator (STATCOM) or a similar device connected to a power system or a failure of one or more components of the STATCOM or some similar device.

To address at least one of this concern and other concerns, a method and a system in accordance with the independent claims are provided. Preferred embodiments are defined by the dependent claims.

According to a first aspect of the present invention, a method is provided. The method is in a system, which system comprises a power supplying and/or absorbing device connected (or connectable) to a power system. The power supplying and/or absorbing device is configured for selectively supplying power to the power system or absorbing power from the power system. The system comprises a voltage sensing unit configured to sense at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage value, thereby producing one or more pluralities of stored values. Each plurality of stored values of the one or more pluralities of stored values represents a transient overvoltage event occurring between two time instants. The method comprises, for each transient overvoltage event, obtaining the plurality of stored values corresponding to the transient overvoltage event, and determining a set of parameters derived from the said plurality of stored values, with the set of parameters characterizing the transient overvoltage event. Thereby, one or more sets of parameters are produced, wherein each set of parameters characterizes the corresponding transient overvoltage event. The method comprises performing, based on the one or more sets of parameters, at least one of a determination of a point in time when maintenance of at least one part of the power supplying and/or absorbing device is to be carried out, or an analysis related to any subsequent malfunction of the power supplying and/or absorbing device.

According to a second aspect of the present invention, a system is provided. The system comprises a power supplying and/or absorbing device connected (or connectable) to a power system. The power supplying and/or absorbing device is configured for selectively supplying power to the power system or absorbing power from the power system. The system comprises a voltage sensing unit configured to sense at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage value, thereby producing one or more pluralities of stored values. Each plurality of stored values of the one or more pluralities of stored values represents a transient overvoltage event occurring between two time instants. The system comprises a controller. The controller is configured to, for each transient overvoltage event, obtain the plurality of stored values corresponding to the transient overvoltage event, and determine a set of parameters derived from the said plurality of stored values, with the set of parameters characterizing the transient overvoltage event. Thereby, one or more sets of parameters are produced, wherein each set of parameters characterizes the corresponding transient overvoltage event. The controller is configured to, based on the one or more sets of parameters, perform at least one of a determination of a point in time when maintenance of at least one part of the power supplying and/or absorbing device is to be carried out, or an analysis related to any subsequent malfunction of the power supplying and/or absorbing device.

The functionality (of, e.g., the voltage sensing unit) of sensing at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage, may for example be implemented in a control system for controlling operation of the power system,. The control system may include or be constituted by the controller and possibly the voltage sensing unit. Such functionality-which herein may be referred to as a transient overvoltage logging function-may be implemented using a fast-sampling time frequency representation recorder in the control system. An example of such a control system is the Modular Advanced Control for HVDC (MACH™) control system developed by the Applicant.

By the configuration of the voltage sensing unit as described herein, triggering of the transient overvoltage logging function in the event of a transient overvoltage event occurring can be carried out automatically. Further, by the configuration of the method or the controller as described herein, the determining of the set(s) of parameters derived from the stored values characterizing the transient overvoltage event(s) can also be carried out automatically, e.g., upon sensing that the transient overvoltage event(s) occurs.

The determining of the set(s) of parameters derived from the stored values characterizing the transient overvoltage event(s) may be implemented by the control system or by a part of the control system. As mentioned, an example of such a control system is MACH™. For example, the determining of the set(s) of parameters derived from the stored values characterizing the transient overvoltage event(s) may be implemented by the MACH Information Monitoring System (MIMS) developed by the Applicant. The MIMS can be easily accessed by a user without the user necessarily needing access to the main MACH computer.

The values indicative of at least one voltage of the power supplying and/or absorbing device at successive time instants which are stored may be stored in a memory of the voltage sensing unit and/or in a memory separate from the voltage sensing unit to which the voltage sensing unit may be connected or connectable. The memory or memories used for the storing may be included in the system. The memory may for example be any combination of read and write memory (RAM) and read only memory (ROM). The memory may comprise persistent storage, which for example can be a magnetic memory, an optical memory, a solid-state memory or a remotely mounted memory, or any combination thereof.

Thus, the system may comprise a memory used for storing the values indicative of at least one voltage of the power supplying and/or absorbing device. For each transient overvoltage event, at least some of the plurality of stored values corresponding to the transient overvoltage event may be deleted from the memory (e.g., by the controller) after the set of parameters characterizing the transient overvoltage event has been determined. For example, only the set(s) of parameters derived from the stored values and characterizing the transient overvoltage event(s) may be stored for subsequent use, whereas the values indicative of at least one voltage of the power supplying and/or absorbing device at successive time instants may be deleted from the memory after the set(s) of parameters has been determined. However, in case of (e.g., extremely) severe transient overvoltage events, the values indicative of at least one voltage of the power supplying and/or absorbing device at successive time instants used to the determine the sets of parameters characterizing the transient overvoltage events may not be deleted but kept for further analysis or visualization on a human-machine interface, for example. In case of implementing the transient overvoltage logging function using a fast-sampling time frequency representation recorder, the number of stored values corresponding to each transient overvoltage event may become very high, and for a very large number of transient overvoltage events, the number of stored values corresponding to the respective ones of the transient overvoltage events may become extremely high. By determining the sets of parameters derived from the stored values characterizing the transient overvoltage events and (e.g., only) storing them for subsequent use while deleting most if not all of the stored values after such determination, the available memory capacity may be utilized more efficiently.

Each or any set of parameters of the one or more sets of parameters may include one or more elements (parameters). Thus, a set of parameters may possibly include only one parameter.

Each or any set of parameters of the one or more sets of parameters may comprise (i) a maximum value of the plurality of stored values corresponding to the transient overvoltage event which corresponds to the set of parameters, (ii) a time difference between the time instants between which the transient overvoltage event which corresponds to the set of parameters occurs, (iii) an integrated value representing an integration of the plurality of stored values corresponding to the transient overvoltage event which corresponds to the set of parameters over the time instants between which the transient overvoltage event which corresponds to the set of parameters occurs, and/or (iv) a maximum value of a derivative of the plurality of stored values corresponding to the transient overvoltage event which corresponds to the set of parameters with respect to the respective time instants between which the transient overvoltage event which corresponds to the set of parameters occurs.

The set of parameters are not limited to the parameters described in the foregoing. For example, the power supplying and/or absorbing device may comprise at least one voltage limiter configured to, in operation, limit the at least one voltage of the power supplying and/or absorbing device to not exceed the threshold voltage value by dissipating electrical power in response to the at least one voltage of the power supplying and/or absorbing device exceeding the threshold voltage. In such a case, each or any set of parameters of the one or more sets of parameters may comprise the electrical power dissipated by the at least one voltage limiter during the transient overvoltage event which corresponds to the set of parameters.

As described herein, based on the one or more sets of parameters, a determination of a point in time when maintenance of at least one part of the power supplying and/or absorbing device is to be carried out and/or an analysis related to any subsequent malfunction of the power supplying and/or absorbing device are performed. Thus, the transient overvoltage logging function as described herein may be used as a basis or tool for predictive maintenance functionality and/or for determination of relations between different transient overvoltage events, or a relatively high occurrence of transient overvoltage events, with any possible malfunction of the power supplying and/or absorbing device, e.g., a failure of a component thereof (or in other words, what is causing component failures over time).

The performing of the analysis related to any subsequent malfunction of the power supplying and/or absorbing device may comprise determining an indication of whether the transient overvoltage event(s) corresponding to the one or more sets of parameters was or were the cause (e.g., the root cause) of any subsequent failure of the power supplying and/or absorbing device.

Transient overvoltages may cause temporary flashover and sparking on insulators and other components of the power supplying and/or absorbing device, which may create and accumulate small conducting particles of coal on such components. After several occurrences of transient overvoltage, the accumulated conducting particles may cause a severe flashover and a component failure. However, by means of a method and a system according to the first and second aspects of the present invention, respectively, when to perform maintenance of at least one part of the power supplying and/or absorbing device, such as cleaning and visual inspection, can be determined based on, e.g., number of occurrences of transient voltage events, their durations, the maximum voltage amplitude during the transient voltage events, etc., instead of only based on a fixed schedule.

The determination of a point in time when maintenance of at least one part of the power supplying and/or absorbing device is to be carried out may be performed by means of a machine learning model.

The method and system according to the first and second aspects of the present invention, respectively, may for example be carried out or implemented in a station or unit connected or connectable to the power system and in which the power supplying and/or absorbing device is included. There may be several such stations or units connected or connectable to the power system, e.g., located at different geographical locations. The producing of one or more sets of parameters characterizing any respective transient overvoltage event(s), and performing, based on the one or more sets of parameters, a determination of a point in time when maintenance of at least one part of the power supplying and/or absorbing device is to be carried out and/or an analysis related to any subsequent malfunction of the power supplying and/or absorbing device as described herein may be carried out for each or any station or unit. As mentioned, the determination of a point in time when maintenance of at least one part of the power supplying and/or absorbing device is to be carried out may be performed by means of a machine learning model. The machine learning model may be trained using data (e.g., the set(s) of parameters) not only derived at the station or unit in which the power supplying and/or absorbing device is included, but also using such data derived at any other station or unit, which may facilitate improving the machine learning model.

In the context of the present application, by maintenance of at least one part of the power supplying and/or absorbing device, it is meant that the maintenance may relate to only one or a few components or to some components included in the power supplying and/or absorbing device. However, the maintenance could possibly relate to the power supplying and/or absorbing device in its entirety.

The components included in the power supplying and/or absorbing device may for example comprise one or more converter cells and/or one or more switching devices. The one or more switching devices may for example be included in any converter cell(s) of the power supplying and/or absorbing device and may for example comprise one or more semiconductor-based switching devices such as, for example, one or more insulated-gate bipolar transistors (IGBTs) and/or another or other types of power semiconductor device having an electronic switching capability.

The transient overvoltage events corresponding to the respective ones the sets of parameters may be non-overlapping in time. The voltage sensor unit may be configured to repeatedly carry out the sensing at least one voltage of the power supplying and/or absorbing device at successive time instants and the storing of values indicative of at least one voltage of the power supplying and/or absorbing device at successive time instants if the sensed at least one voltage of the power supplying and/or absorbing device exceeds a threshold voltage value until the sensed at least one voltage of the power supplying and/or absorbing device does not exceed the threshold voltage value. Thereby, several pluralities of stored values indicative of at least one voltage of the power supplying and/or absorbing device at successive time instants may be produced, representing a plurality of transient overvoltage events non-overlapping in time.

The power supplying and/or absorbing device may comprise, but is not limited to, a Voltage Source Converter (VSC) based device, a Static Synchronous Compensator (STATCOM), a static VAR compensator (SVC), a series compensation system, a High Voltage Direct Current (HVDC) transmission line, and/or a multi-level converter.

It is to be understood that in the context of the present application, the term HVDC transmission line may not only encompass one or more conductors (e.g., transmission lines), but may encompass one or more additional components such as, for example, one or more converters or converter stations, at at least the end of the HVDC transmission line which may be connected to the power system.

The transient overvoltage logging function as described herein may be used for one or more voltages of the power supplying and/or absorbing device. The transient overvoltage logging function as described herein may be used for both primary and secondary voltages, and/or for voltage on the direct current (DC) side in an E-STATCOM (energy storage and STATCOM) or back-to-back configuration.

For example, the power supplying and/or absorbing device may comprise a transformer via which one or more other components of the power supplying and/or absorbing device is connected to the power system. The transformer may comprise one or more primary windings connected to the one or more other components and one or more secondary windings connected to the power system. In such a case, the at least one voltage of the power supplying and/or absorbing device may comprise a voltage of the one or more primary windings and/or a voltage of the one or more secondary windings. The transformer may be a multi-phase transformer. In such a case, the at least one voltage of the power supplying and/or absorbing device may comprise a voltage of the one or more primary windings for each of the phases and/or a voltage of the one or more secondary windings for each of the phases.

According to another example, the power supplying and/or absorbing device may, in addition or in alternative, comprise a converter configured to convert direct current (DC) power to alternating current (AC) power, or vice versa. In such a case, the at least one voltage of the power supplying and/or absorbing device may comprise a voltage on the DC side of the converter.

According to another example, the power supplying and/or absorbing device may, in addition or in alternative, comprise a multi-phase transformer via which one or more other components of the power supplying and/or absorbing device may be connected to the power system. The multi-phase transformer may comprise one or more primary windings connected to the one or more other components and one or more secondary windings connected to the power system. The at least one voltage of the power supplying and/or absorbing device may comprise a voltage of the one or more primary windings for each of the phases and/or a voltage of the one or more secondary windings for each of the phases. For each transient overvoltage event, and for each phase, the plurality of stored values corresponding to the transient overvoltage event may be obtained (e.g., by the controller), and a set of parameters derived from the said plurality of stored values may be determined (e.g., by the controller), the set of parameters characterizing the transient overvoltage event for the phase. Thereby, several sets of parameters including one or more sets of parameters for each phase may be produced. The performing of at least one of a determination of a point in time when maintenance of at least one part of the power supplying and/or absorbing device is to be carried out or an analysis related to any subsequent malfunction of the power supplying and/or absorbing device may be based on the several sets of parameters and may be carried out for each of the respective phases individually.

A method and a system according to the first and second aspects of the present invention, respectively, are not necessarily limited to sensing voltage(s) of the power supplying and/or absorbing device at successive time instants, but may also sense, e.g., currents thereof. To that end, the system may comprise a current sensing unit. The current sensing unit may be configured to sense at least one current of the power supplying and/or absorbing device at successive time instants. The current sensing unit may be configured to, for each transient overvoltage event, store current values indicative of at least one current of the power supplying and/or absorbing device at the time instants corresponding to the stored values which correspond to the transient overvoltage event. For each transient overvoltage event, the plurality of stored current values corresponding to the transient overvoltage event may be obtained (e.g., by the controller). For each transient overvoltage event, the set of parameters corresponding to the transient overvoltage event may be derived further from the plurality of stored current values corresponding to the transient overvoltage event. Thus, the current sensing unit may be configured to sense overcurrent(s) caused by the transient overvoltage(s). As mentioned in the foregoing, the power supplying and/or absorbing device may comprise a converter configured to convert DC power to AC power, or vice versa. The at least one current of the power supplying and/or absorbing device may for example comprise current input into the converter of the power supplying and/or absorbing device. Storing current values indicative of at least one current of the power supplying and/or absorbing device at the time instants corresponding to the stored values which correspond to a transient overvoltage event can facilitate matching possible component (e.g., an IGBT) failures related to external faults (e.g., the overvoltage). Deriving the set of parameters corresponding to a transient overvoltage event further from the plurality of stored current values corresponding to the transient overvoltage event may entail including current values indicative of at least one current of the power supplying and/or absorbing device at the time instants corresponding to the stored values which correspond to the transient overvoltage event in the set of parameters. However, it may in alternative or in addition entail including one or more derived parameters, such as for example a maximum value of the plurality of stored current values corresponding to the transient overvoltage event.

In the context of the present application, by values indicative of at least one voltage of the power supplying and/or absorbing device at successive time instants, it may be meant voltage sensed or measured at discrete time instants, or, e.g., average values of voltage sensed or measured over certain time periods in which the successive time instants are included. Similarly, by current values indicative of at least one current of the power supplying and/or absorbing device at the time instants corresponding to the stored values which correspond to the transient overvoltage event, it may be meant current sensed or measured at discrete time instants corresponding to said time instants, or, e.g., average values of voltage sensed or measured over certain time periods in which the said time instants are included.

The current sensing unit may for example comprise one or more current transducers and/or one or more current transformers, and/or any other appropriate type of current sensor, e.g., as known in the art.

The voltage sensing unit may for example comprise one or more voltage transducers and/or one or more potential transformers, and/or any other appropriate type of voltage sensor, e.g., as known in the art.

The controller may in alternative be referred to as a control unit, a control module, etc. The controller may for example include or be constituted by any suitable central processing unit (CPU), microcontroller, digital signal processor (DSP), Application Specific Integrated Circuit (ASIC), Field Programmable Gate Array (FPGA), etc., or any combination thereof. The controller may optionally be capable of executing software instructions stored in a computer program product, e.g., in the form of a memory. The memory may for example be any combination of read and write memory (RAM) and read only memory (ROM). The memory may comprise persistent storage, which for example can be a magnetic memory, an optical memory, a solid-state memory or a remotely mounted memory, or any combination thereof.

According to a third aspect of the present invention, a computer program is provided. The computer program comprises instructions, which when executed by one or more processors comprised in a controller of a system according to the second aspect of the present invention, cause the controller to perform a method according to the first aspect of the present invention.

According to a fourth aspect of the present invention, a computer-readable (or processor-readable) storage medium is provided. The computer-readable storage medium has instructions stored thereon, which when executed by one or more processors comprised in a controller of a system according to the second aspect of the present invention, cause the controller to perform a method according to the first aspect of the present invention.

Each or any of the one or more processors may for example comprise a CPU, a microcontroller, a DSP, an ASIC, an FPGA, etc., or any combination thereof.

The computer-readable storage medium may for example include a Digital Versatile Disc (DVD) or a floppy disk or any other suitable type of computer-readable means or computer-readable (digital) medium, such as, but not limited to, a memory such as, for example, nonvolatile memory, a hard disk drive, a Compact Disc (CD), a Flash memory, magnetic tape, a Universal Serial Bus (USB) memory device, a Zip drive, etc.

According to a fifth aspect of the present invention, an arrangement is provided. The arrangement comprises a power system and a system according to the second aspect of the present invention, wherein the power supplying and/or absorbing device of the system is connected to the power system.

Further objects and advantages of the present invention are described in the following by means of exemplifying embodiments. It is noted that the present invention relates to all possible combinations of features recited in the claims. Further features of, and advantages with, the present invention will become apparent when studying the appended claims and the description herein. Those skilled in the art realize that different features of the present invention can be combined to create embodiments other than those described herein.

### BRIEF DESCRIPTION OF THE DRAWINGS

Exemplifying embodiments of the present invention will be described below with reference to the accompanying drawings.

FIG. 1 is a schematic view of a system according to an embodiment of the present invention.

FIG. 2 is a schematic graph for illustrating principles of one or more embodiments of the present invention.

FIG. 3 is a schematic flowchart of a method according to an embodiment of the present invention.

All the figures are schematic, not necessarily to scale, and generally only show parts which are necessary in order to elucidate embodiments of the present invention, wherein other parts may be omitted or merely suggested.

### DETAILED DESCRIPTION

The present invention will now be described hereinafter with reference to the accompanying drawings, in which exemplifying embodiments of the present invention are shown. The present invention may, however, be embodied in many different forms and should not be construed as limited to the embodiments of the present invention set forth herein; rather, these embodiments are provided by way of example so that this disclosure will convey the scope of the present invention to those skilled in the art.

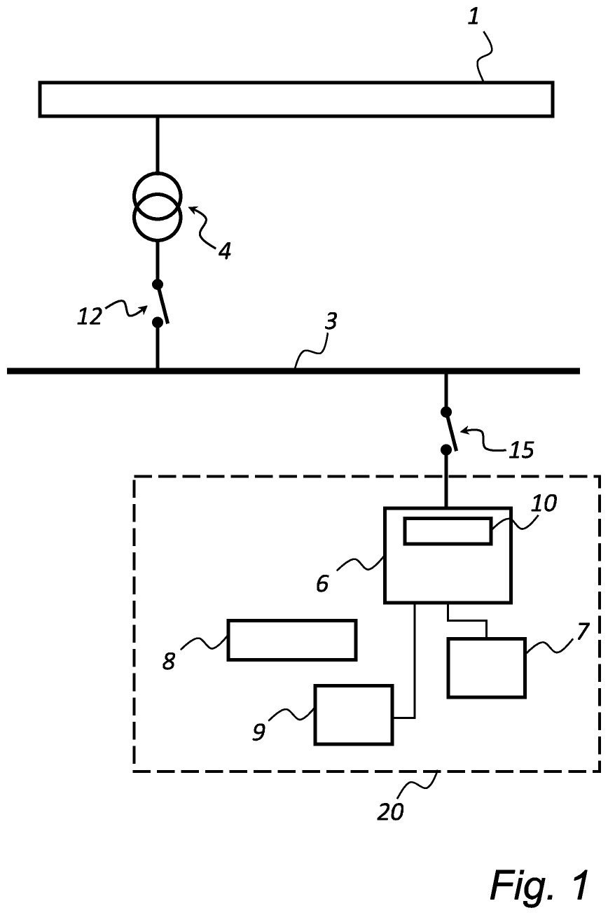

FIG. 1 is a schematic view of a system 20 according to an embodiment of the present invention. The system 20 comprises a power supplying and/or absorbing device 6 which is connected or connectable to a power system 1 and configured for selectively supplying power to the power system 1 or absorbing power from the power system 1. The power system 1 may for example comprise a power transmission and/or distribution system. The power system 1 may for example comprise a power grid, e.g., a power transmission and/or distribution grid. The power supplied to the load power system 1 or absorbed from the power system 1 by the power supplying and/or absorbing device 6 may be governed at least by a voltage reference value of the power supplying and/or absorbing device 6.

In accordance with the embodiment of the present invention illustrated in FIG. 1, the power supplying and/or absorbing device 6 may be connected or connectable, e.g., via a switch 15 as illustrated in FIG. 1, to a conductor 3 to which also the power system 1 is connected or connectable, e.g., via a switch 12 as illustrated in FIG. 1. Thus, the power supplying and/or absorbing device 6 may be connected to the power system 1 via the conductor 3 and may be configured for selectively supplying power to the conductor 3 or absorbing power from the conductor 3 to thereby supply power to the power system 1 or absorb power from the power system 1 via the conductor 3. The power system 1 may be connected or connectable to the conductor 3 via a transformer 4. The conductor 3 may for example comprise a bus, or busbar. There may be one or more loads (not shown in FIG. 1) connected or connectable to the conductor 3, which hence may be referred to as a load conductor. The switch 12 and/or the switch 15 may be normally closed, e.g., so that the switch 12 and the switch 15, respectively, conduct current therethrough.

The power supplying and/or absorbing device 6 may for example be based on or comprise a Voltage Source Converter (VSC) based device, a Static Synchronous Compensator (STATCOM), a static VAR compensator (SVC), a series compensation system, a High Voltage Direct Current (HVDC) transmission line, and/or a multi-level converter. The STATCOM may for example have a delta topology. However, the STATCOM is not limited thereto, and could in alternative have, e.g., a wye topology. The multi-level converter may for example comprise a three-level converter.

For example, in case the power supplying and/or absorbing device 6 is based on a STATCOM having a delta topology, the power supplying and/or absorbing device 6 may be connected to the conductor 3 at, or via a conductor connected to, a corner point (e.g., terminal) of the delta topology-configured STATCOM. The power supplying and/or absorbing device 6 may be directly connected to the conductor 3 or may be indirectly connected to the conductor 3 (e.g., via one or more intermediate devices or components).

The system 20 comprises a voltage sensing unit 7, which is configured to sense at least one voltage of the power supplying and/or absorbing device 6 at successive time instants, and if the sensed at least one voltage of the power supplying and/or absorbing device 6 at a time instant exceeds a threshold voltage value, store values indicative of at least one voltage of the power supplying and/or absorbing device 6 at successive time instants until the sensed at least one voltage of the power supplying and/or absorbing device 6 does not exceed the threshold voltage value, thereby producing one or more pluralities of stored values, each plurality of stored values of the one or more pluralities of stored values representing a transient overvoltage event occurring between two time instants.

The system 20 comprises a controller 8. The controller 8 is configured to, for each transient overvoltage event: (i) obtain the plurality of stored values corresponding to the transient overvoltage event, and (ii) determine a set of parameters derived from the said plurality of stored values, the set of parameters characterizing the transient overvoltage event. Thereby, one or more sets of parameters are produced, wherein each set of parameters characterizes the corresponding transient overvoltage event.

The controller 8 is configured to, based on the one or more sets of parameters, perform at least one of: a determination of a point in time when maintenance of at least one part of the power supplying and/or absorbing device 6 is to be carried out, or an analysis related to any subsequent malfunction of the power supplying and/or absorbing device 6.

In accordance with the embodiment of the present invention illustrated in FIG. 1, the power supplying and/or absorbing device 6 may comprise a transformer, which is schematically indicated at 10. One or more components (not shown in FIG. 1) of the power supplying and/or absorbing device 6 other than the transformer 10 may be connected to the power system 1 via the transformer 10. The transformer 10 may comprise one or more primary windings (not shown in FIG. 1) connected to the one or more other components and one or more secondary windings (not shown in FIG. 1) connected to the power system 1.

The at least one voltage of the power supplying and/or absorbing device 6 may comprise a voltage of the one or more primary windings and/or a voltage of the one or more secondary windings. The transformer 10 may be a multi-phase transformer, wherein the at least one voltage of the power supplying and/or absorbing device 6 may comprise a voltage of the one or more primary windings for each of the phases and/or a voltage of the one or more secondary windings for each of the phases.

The functionality of sensing at least one voltage of the power supplying and/or absorbing device 6 at successive time instants, and if the sensed at least one voltage of the power supplying and/or absorbing device 6 at a time instant exceeds a threshold voltage value, store values indicative of at least one voltage of the power supplying and/or absorbing device 6 at successive time instants until the sensed at least one voltage of the power supplying and/or absorbing device 6 does not exceed the threshold voltage, may be implemented in a control system, e.g., for controlling operation of the power system 1, which control system may include or be constituted by the controller 8 and possibly the voltage sensing unit 7. Such functionality may for example be implemented using a fast-sampling time frequency representation recorder in the control system.

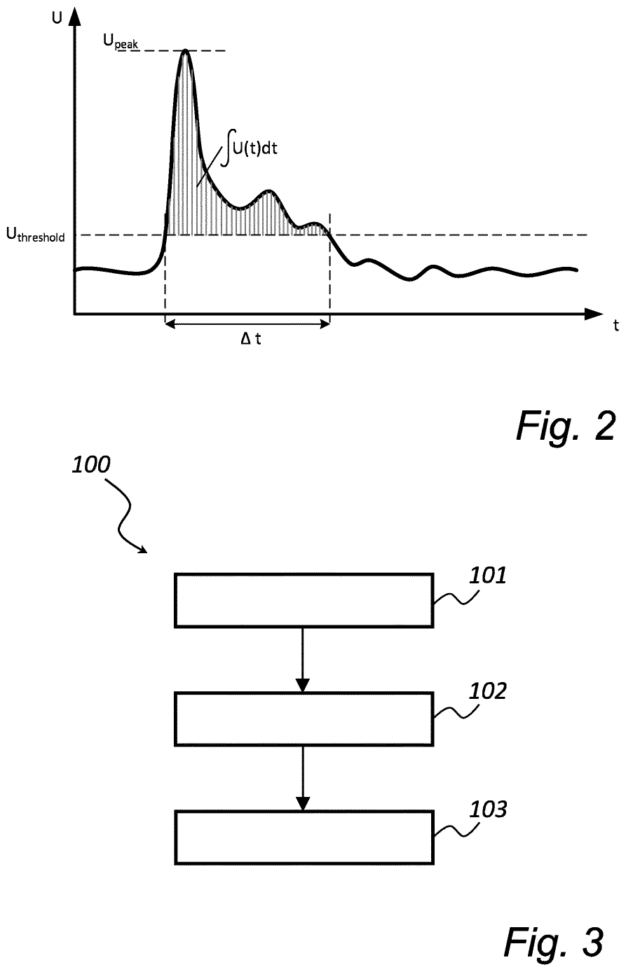

FIG. 2 is a schematic graph for illustrating principles of one or more embodiments of the present invention. FIG. 2 is a schematic graph of a voltage U of the power supplying and/or absorbing device versus time t during a transient overvoltage event, with the voltage U and time t being in arbitrary units. The voltage U may be sampled with a very high frequency to produce a plurality of values of the voltage U of the power supplying and/or absorbing device at successive time instants. For illustrating principles of one or more embodiments of the present invention, the voltage U is shown in FIG. 2 as a continuous function of time 7. The transient overvoltage event can be defined as when the voltage U exceeds the threshold voltage value U_{threshold} shown in FIG. 2.

The set of parameters corresponding to the transient overvoltage event may include a maximum value, or peak value, of the voltage U during the transient overvoltage event, denoted by Uₚₑₐₖ in FIG. 2.

The set of parameters corresponding to the transient overvoltage event may, in addition or in alternative, include a time difference between the time instants between which the transient overvoltage event occurs, denoted by At in FIG. 2.

The set of parameters corresponding to the transient overvoltage event may, in addition or in alternative, include an integrated value representing an integration of the voltage U over the time instants between which the transient overvoltage event occurs, indicated by ∫U(t)dt in FIG. 2.

The set of parameters corresponding to the transient overvoltage event may, in addition or in alternative, include a maximum value of a derivative of the voltage U with respect to time over the time instants between which the transient overvoltage event occurs.

With further reference to FIG. 1 and in accordance with the embodiment of the present invention illustrated in that figure, the system 20 may optionally comprise a current sensing unit 9. The current sensing unit 9 may be configured to sense at least one current of the power supplying and/or absorbing device 6 at successive time instants. The current sensing unit 9 may be configured to, for each transient overvoltage event, store current values indicative of at least one current of the power supplying and/or absorbing device 6 at the time instants corresponding to the stored values which correspond to the transient overvoltage event. The controller 8 may be configured to, for each transient overvoltage event, obtain the plurality of stored current values corresponding to the transient overvoltage event. For each transient overvoltage event, the set of parameters corresponding to the transient overvoltage event may be derived further from the plurality of stored current values corresponding to the transient overvoltage event.

As indicated in FIG. 1, the power supplying and/or absorbing device 6 may be coupled to the voltage sensing unit 7 and the current sensing unit 9, respectively.

As mentioned, the controller 8 is configured to, for each transient overvoltage event, obtain the plurality of stored values corresponding to the transient overvoltage event, and possible also obtain the plurality of stored current values corresponding to the transient overvoltage event. To that end, the controller 8 may be communicatively connected with the voltage sensing unit 7 and the current sensing unit 9, respectively. By the controller 8 being communicatively connected with the voltage sensing unit 7 and the current sensing unit 9, respectively, it is herein meant that the controller 8 and the voltage sensing unit 7 and the current sensing unit 9, respectively, are able to communicate via wired and/or wireless communication means or techniques, for example via any appropriate wired and/or wireless communication means or techniques as known in the art, for transmitting messages, instructions, data, commands, etc., from the voltage sensing unit 7 or the current sensing unit 9 to the controller 8, and possibly vice versa. Wireless communication means may for example comprise radio frequency (RF) communication, infrared communication (e.g., employing a communication link employing infrared light) or another type of free-space optical communication. Wired communication means may for example comprise at least one optical waveguide, or optical transmission line (e.g., an optical fiber), and/or at least one electrical conductor (e.g., a cable or wire, e.g., a copper conductor or cable, or copper wire).

FIG. 3 is a schematic flowchart of a method 100 according to an embodiment of the present invention. The method 100 is in a system, which comprises a power supplying and/or absorbing device connected (or connectable) to a power system. The power supplying and/or absorbing device is configured for selectively supplying power to the power system or absorbing power from the power system. The system comprises a voltage sensing unit configured to sense at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage value, thereby producing one or more pluralities of stored values. Each plurality of stored values of the one or more pluralities of stored values represents a transient overvoltage event occurring between two time instants.

The method 100 comprises at 101, for each transient overvoltage event, obtaining the plurality of stored values corresponding to the transient overvoltage event, and, at 102, determining a set of parameters derived from the said plurality of stored values, with the set of parameters characterizing the transient overvoltage event. Thereby, one or more sets of parameters are produced, wherein each set of parameters characterizes the corresponding transient overvoltage event.

The method 100 comprises, at 103, performing, based on the one or more sets of parameters, at least one of a determination of a point in time when maintenance of at least one part of the power supplying and/or absorbing device is to be carried out, or an analysis related to any subsequent malfunction of the power supplying and/or absorbing device.

In conclusion, a system is disclosed, comprising a power supplying and/or absorbing device, connected to a power system and configured for selectively supplying power to the power system or absorbing power from the power system, and a voltage sensing unit configured to sense at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage value, thereby producing one or more pluralities of stored values each of which represents a transient overvoltage event. A controller is configured to, for each transient overvoltage event, obtain the plurality of stored values corresponding to the transient overvoltage event and determine a set of parameters derived from the said plurality of stored values, thereby producing one or more sets of parameters each of which characterizes the corresponding transient overvoltage event.

While the present invention has been illustrated in the appended drawings and the foregoing description, such illustration is to be considered illustrative or exemplifying and not restrictive; the present invention is not limited to the disclosed embodiments. Other variations to the disclosed embodiments can be understood and effected by those skilled in the art in practicing the claimed invention, from a study of the drawings, the disclosure, and the appended claims. In the appended claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A method in a system comprising a power supplying and/or absorbing device connected to a power system and configured for selectively supplying power to the power system or absorbing power from the power system, the system further comprising a voltage sensing unit configured to sense at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage value, thereby producing one or more pluralities of stored values, each plurality of stored values of the one or more pluralities of stored values representing a transient overvoltage event occurring between two time instants, the method comprising, for each transient overvoltage event:
obtaining the plurality of stored values corresponding to the transient overvoltage event; and
determining a set of parameters derived from the said plurality of stored values, the set of parameters characterizing the transient overvoltage event, thereby producing one or more sets of parameters, wherein each set of parameters characterizes the corresponding transient overvoltage event;
the method further comprising:
based on the one or more sets of parameters, performing at least one of: a determination of a point in time when maintenance of at least one part of the power supplying and/or absorbing device is to be carried out, or an analysis related to any subsequent malfunction of the power supplying and/or absorbing device.

2. The method according to claim 1, wherein the performing of the analysis related to any subsequent malfunction of the power supplying and/or absorbing device comprises determining an indication of whether the transient overvoltage event(s) corresponding to the one or more sets of parameters was or were the cause of any subsequent failure of the power supplying and/or absorbing device.

3. The method according to claim 1, wherein each set of parameters of the one or more sets of parameters comprises one or more of:
a maximum value of the plurality of stored values corresponding to the transient overvoltage event which corresponds to the set of parameters;
a time difference between the time instants between which the transient overvoltage event which corresponds to the set of parameters occurs;
an integrated value representing an integration of the plurality of stored values corresponding to the transient overvoltage event which corresponds to the set of parameters over the time instants between which the transient overvoltage event which corresponds to the set of parameters occurs; or
a maximum value of a derivative of the plurality of stored values corresponding to the transient overvoltage event which corresponds to the set of parameters with respect to the respective time instants between which the transient overvoltage event which corresponds to the set of parameters occurs.

4. The method according to claim 1, wherein the power supplying and/or absorbing device comprises at least one voltage limiter configured to, in operation, limit the at least one voltage of the power supplying and/or absorbing device to not exceed the threshold voltage value by dissipating electrical power in response to the at least one voltage of the power supplying and/or absorbing device exceeding the threshold voltage, wherein each set of parameters of the one or more sets of parameters comprises the electrical power dissipated by the at least one voltage limiter during the transient overvoltage event which corresponds to the set of parameters.

5. The method according to claim 1, wherein the power supplying and/or absorbing device comprises a multi-phase transformer via which one or more other components of the power supplying and/or absorbing device are connected to the power system, wherein the multi-phase transformer comprises one or more primary windings connected to the one or more other components and one or more secondary windings connected to the power system, and wherein the at least one voltage of the power supplying and/or absorbing device comprises a voltage of the one or more primary windings for each of the phases and/or a voltage of the one or more secondary windings for each of the phases, the method comprising, for each transient overvoltage event, and for each phase:
obtaining the plurality of stored values corresponding to the transient overvoltage event; and
determining a set of parameters derived from the said plurality of stored values, the set of parameters characterizing the transient overvoltage event for the phase, thereby producing several sets of parameters including one or more sets of parameters for each phase;
wherein the performing of at least one of a determination of a point in time when maintenance of at least one part of the power supplying and/or absorbing device is to be carried out or an analysis related to any subsequent malfunction of the power supplying and/or absorbing device is based on the several sets of parameters and is carried out for each of the respective phases individually.

6. The method according to claim 1, wherein the voltage sensor unit is configured to repeatedly carry out the sensing at least one voltage of the power supplying and/or absorbing device at successive time instants and the storing of values indicative of at least one voltage of the power supplying and/or absorbing device at successive time instants if the sensed at least one voltage of the power supplying and/or absorbing device exceeds a threshold voltage value until the sensed at least one voltage of the power supplying and/or absorbing device does not exceed the threshold voltage value, so as to produce several pluralities of stored values indicative of at least one voltage of the power supplying and/or absorbing device at successive time instants representing a plurality of transient overvoltage events non-overlapping in time.

7. The method according to claim 1, wherein the system further comprises a memory used for storing the values indicative of at least one voltage of the power supplying and/or absorbing device, wherein the method further comprises, for each transient overvoltage event:
after the set of parameters characterizing the transient overvoltage event has been determined, deleting at least some of the plurality of stored values corresponding to the transient overvoltage event from the memory.

8. The method according to claim claim 1, wherein the system further comprises a current sensing unit configured to sense at least one current of the power supplying and/or absorbing device at successive time instants, wherein the current sensing unit is configured to, for each transient overvoltage event, store current values indicative of at least one current of the power supplying and/or absorbing device at the time instants corresponding to the stored values which correspond to the transient overvoltage event, the method further comprising, for each transient overvoltage event:
obtaining the plurality of stored current values corresponding to the transient overvoltage event;
wherein for each transient overvoltage event, the set of parameters corresponding to the transient overvoltage event is derived further from the plurality of stored current values corresponding to the transient overvoltage event.

9. The method according to claim 1, wherein the determination of a point in time when maintenance of at least one part of the power supplying and/or absorbing device is to be carried out is performed by means of a machine learning model.

10. A system comprising:
a power supplying and/or absorbing device connected to a power system and configured for selectively supplying power to the power system or absorbing power from the power system;
a voltage sensing unit configured to sense at least one voltage of the power supplying and/or absorbing device at successive time instants, and if the sensed at least one voltage of the power supplying and/or absorbing device at a time instant exceeds a threshold voltage value, store values indicative of at least one voltage of the power supplying and/or absorbing device at successive time instants until the sensed at least one voltage of the power supplying and/or absorbing device does not exceed the threshold voltage value, thereby producing one or more pluralities of stored values, each plurality of stored values of the one or more pluralities of stored values representing a transient overvoltage event occurring between two time instants; and
a controller configured to, for each transient overvoltage event:
obtain the plurality of stored values corresponding to the transient overvoltage event; and
determine a set of parameters derived from the said plurality of stored values, the set of parameters characterizing the transient overvoltage event, thereby producing one or more sets of parameters, wherein each set of parameters characterizes the corresponding transient overvoltage event; and
wherein the controller is further configured to:
based on the one or more sets of parameters, perform at least one of: a determination of a point in time when maintenance of at least one part of the power supplying and/or absorbing device is to be carried out, or an analysis related to any subsequent malfunction of the power supplying and/or absorbing device.

11. The system according to claim 10, wherein the voltage sensor unit is configured to repeatedly carry out the sensing at least one voltage of the power supplying and/or absorbing device at successive time instants and the storing of values indicative of at least one voltage of the power supplying and/or absorbing device at successive time instants if the sensed at least one voltage of the power supplying and/or absorbing device exceeds a threshold voltage value until the sensed at least one voltage of the power supplying and/or absorbing device does not exceed the threshold voltage value, so as to produce several pluralities of stored values indicative of at least one voltage of the power supplying and/or absorbing device at successive time instants representing a plurality of transient overvoltage events non-overlapping in time.

12. The system according to claim 10, wherein the power supplying and/or absorbing device comprises one or more of a Voltage Source Converter (VSC) based device, a Static Synchronous Compensator (STATCOM) a static VAR compensator (SVC) a series compensation system, a High Voltage Direct Current (HVDC) transmission line, or a multi-level converter.

13. The system according to claim 10, wherein the power supplying and/or absorbing device comprises a transformer via which one or more other components of the power supplying and/or absorbing device is connected to the power system, wherein the transformer comprises one or more primary windings connected to the one or more other components and one or more secondary windings connected to the power system, wherein the at least one voltage of the power supplying and/or absorbing device comprises a voltage of the one or more primary windings and/or a voltage of the one or more secondary windings.

14. The system according to claim 13, wherein the transformer is a multi-phase transformer, and wherein the at least one voltage of the power supplying and/or absorbing device comprises a voltage of the one or more primary windings for each of the phases and/or a voltage of the one or more secondary windings for each of the phases.

15. The system according to claim 10, wherein the power supplying and/or absorbing device comprises a converter configured to convert direct current (DC) power to alternating current (AC) power, or vice versa, wherein the at least one voltage of the power supplying and/or absorbing device comprises a voltage on the DC side of the converter.

16. The system according to claim 10, further comprising:
a current sensing unit configured to sense at least one current of the power supplying and/or absorbing device at successive time instants, wherein the current sensing unit is configured to, for each transient overvoltage event, store current values indicative of at least one current of the power supplying and/or absorbing device at the time instants corresponding to the stored values which correspond to the transient overvoltage event;
wherein the controller is further configured to, for each transient overvoltage event, obtain the plurality of stored current values corresponding to the transient overvoltage event;
wherein for each transient overvoltage event, the set of parameters corresponding to the transient overvoltage event is derived further from the plurality of stored current values corresponding to the transient overvoltage event.

17. (canceled)

18. A non-transitory computer-readable storage medium on which instructions are stored, which when executed by one or more processors comprised in a controller, cause the controller to perform the method according to claim 1.
